(19) United States
(12) Patent Application Publication
(10) Pub. No.: US 2011/0043190 A1
(43) Pub. Date: Feb. 24, 2011

(54) ROGOWSKI COIL, MEDIUM VOLTAGE ELECTRICAL APPARATUS INCLUDING THE SAME, AND METHOD OF PROVIDING ELECTROSTATIC SHIELDING FOR A ROGOWSKI COIL

(76) Inventor: LAWRENCE B. FARR, Asheville, NC (US)

Correspondence Address: Martin J. Moran;Eaton Electrical, Inc., 1000 Cherrington Parkway, Moon Township, PA, 15108, US

(21) Appl. No.: 12/544,496

(22) Filed: Aug. 20, 2009

(51) Int. Cl. G01R 1/20; H01F 27/36

(52) U.S. Cl. 324/126; 336/84 R

(57) ABSTRACT

A Rogowski coil includes a core, a Rogowski coil winding disposed on the core, an insulator disposed on the Rogowski coil winding disposed on the core, and a conductive winding disposed on the insulator disposed on the Rogowski coil winding disposed on the core. The conductive winding includes an electrical connection structured to be grounded. When the conductive winding is grounded, the grounded conductive winding provides electrostatic shielding for the Rogowski coil winding of the Rogowski coil.

### BACKGROUND

1. Field

The disclosed concept pertains generally to medium voltage electrical apparatus and, more particularly, to such medium voltage electrical apparatus including a number of Rogowski coils. The disclosed concept also pertains to Rogowski coils. The disclosed concept further pertains to methods of providing electrostatic shielding for Rogowski coils.

2. Background Information

A Rogowski coil is an electrical device for measuring alternating current (AC) or high speed current pulses. The Rogowski coil includes, for example, a helical coil of wire, which is wound around a nonmetallic core.

Another type of Rogowski coil includes first and second helical coils of wire (loops) electrically connected in series with each other. The first loop is wound with a substantially constant winding density in a first direction around a core that has a substantially constant cross section. The second loop is wound with a substantially constant winding density in a second direction around a core that has a substantially constant cross section. A conductor (e.g., a power line) whose current is to be measured traverses through the loops. A voltage may be induced in the coil based on the rate of change of the current running through the power line. Rogowski coils may have other configurations as well. See U.S. Pat. Appl. Pub. No. 2009/0115427.

Pat. Appl. Pub. No. 2009/0115427 also discloses that a Rogowski coil may include an air core (or other dielectric core) rather than an iron core, which gives the coil a low inductance and an ability to respond to fast-changing currents. Further, the Rogowski coil typically is highly linear, even when subjected to large currents, such as those of low voltage and medium voltage power lines. By forming the Rogowski coil with equally spaced windings, effects of electromagnetic interference may be substantially avoided.

The voltage that is induced in the Rogowski coil is proportional to the rate of change of current in the conductor. The output of the Rogowski coil is usually connected to an integrator in order to provide an output signal that is proportional to current.

For sensitive ground fault detection applications, two sets of Rogowski coils are electrically connected in series. The first set of Rogowski coils is used for motor protection and the second set of Rogowski coils is used for ground fault protection.

When used in medium voltage applications, Rogowski coils are subject to electrostatic interference due to their relatively close proximity to medium voltage conductors.

Some known Rogowski coils employ a copper foil inside a non-conductive case in order to seek to isolate the internal coil from electrostatic interference.

It is known to ground the copper foil of a Rogowski coil. However, the copper foil does not lay flat on a curved surface of a core and, as a result, is subject to being wrinkled or otherwise altered or damaged.

Alternatively, it is known to employ a complex plastic copper-coated electrostatic shield for the Rogowski coil. However, such plastic copper-coated electrostatic shields are relatively expensive.

U.S. Pat. Appl. Pub. No. 2008/0106241 discloses a power line current sensor device including a Rogowski coil having two loops, an integrator and an interface. Each loop has a first end and a second end. The two loops bring the two ends toward each other, while leaving space between the ends, in order that the Rogowski coil is readily installed at a power line. The coil of the Rogowski coil includes a first winding wound in a first direction, and a second winding wound in a second direction. The windings each include traces on a printed circuit board. As alternating current flows through the power line, a magnetic field is generated inducing an electrical field (i.e., voltage) within each winding of the Rogowski coil. However, other sources of electromagnetic interference also may induce current flow in the windings. By including a left-hand winding and a right-hand winding (i.e., windings in substantially opposite directions) with equally spaced windings, the effects from external sources are largely cancelled out. In particular, external fields from sources outside the Rogowski coil, such as other power lines or power line communication and distribution equipment, generate equal but opposite electrical flow in the windings.

Rogowski coils are relatively insensitive to effects from external sources, which are largely cancelled out. However, when mounted in close proximity to an external noise source (e.g., without limitation, as close as about two inches to a power line), the effects are significant and additional measures are needed.

There is room for improvement in Rogowski coils.

There is further room for improvement in medium voltage electrical apparatus including Rogowski coils.

There is still further room for improvement in methods of providing electrostatic shielding for Rogowski coils.

### SUMMARY

These needs and others are met by embodiments of the disclosed concept, which provide isolation for a Rogowski coil to eliminate electrostatic interference.

In accordance with one aspect of the disclosed concept, a Rogowski coil comprises: a core; a Rogowski coil winding disposed on the core; an insulator disposed on the Rogowski coil winding disposed on the core; and a conductive winding disposed on the insulator disposed on the Rogowski coil winding disposed on the core, the conductive winding including an electrical connection structured to be grounded, wherein when the conductive winding is grounded, the grounded conductive winding provides electrostatic shielding for the Rogowski coil winding of the Rogowski coil.

The conductive winding and the insulator may be formed by a shoulder-to-shoulder winding of an insulated conductor wound on the Rogowski coil winding to isolate the Rogowski coil winding from medium voltage electrostatic interference.

The conductive winding may be an isolation coil wound shoulder-to-shoulder on the insulator; and the isolation coil may be grounded at one end thereof to isolate the Rogowski coil winding.

The Rogowski coil winding may be formed as a first layer, the conductive winding may be formed as a second layer on the first layer, and the first and second layers may be evenly distributed layers on the core.

The Rogowski coil winding may be wound in a first winding direction, and the conductive winding may be wound in an opposite second winding direction.

As another aspect of the disclosed concept, a medium voltage electrical apparatus comprises: at least one pole comprising: a medium voltage conductor, and a Rogowski coil comprising: a core including an opening, a Rogowski coil winding disposed on the core, the Rogowski coil winding defining an output, an insulator disposed on the Rogowski coil winding disposed on the core, and a conductive winding disposed on the insulator disposed on the Rogowski coil winding disposed on the core, the conductive winding including an electrical connection structured to be grounded; a sensor circuit including an input electrically interconnected with the output of the Rogowski coil and an output having a value corresponding to current flowing through the medium voltage conductor; and a processor cooperating with the sensor circuit to provide a value of the current flowing through the medium voltage conductor, wherein the medium voltage conductor passes through the opening of the core, and wherein when the conductive winding is grounded, the grounded conductive winding provides electrostatic shielding for the Rogowski coil winding of the Rogowski coil.

The grounded conductive winding may be structured to provide electrostatic shielding from medium voltage electrostatic interference for the Rogowski coil winding of the Rogowski coil.

The conductive winding and the insulator may be formed by a shoulder-to-shoulder winding of an insulated conductor wound on the Rogowski coil winding to isolate the Rogowski coil winding from medium voltage electrostatic interference.

The conductive winding may be an isolation coil wound shoulder-to-shoulder on the insulator; and wherein the isolation coil may be grounded at one end thereof to isolate the Rogowski coil winding.

As another aspect of the disclosed concept, a method provides electrostatic shielding for a Rogowski coil. The method comprises: disposing a Rogowski coil winding on a core; disposing an insulator on the Rogowski coil winding disposed on the core; disposing a conductive winding on the insulator disposed on the Rogowski coil winding disposed on the core; grounding the conductive winding; and providing electrostatic shielding for the Rogowski coil winding of the Rogowski coil with the grounded conductive winding.

The method may further comprise forming the conductive winding and the insulator by a shoulder-to-shoulder winding of an insulated conductor wound on the Rogowski coil winding to isolate the Rogowski coil winding from medium voltage electrostatic interference.

The method may further comprise forming the conductive winding from an isolation coil wound shoulder-to-shoulder on the insulator; and grounding the isolation coil at one end thereof to isolate the Rogowski coil winding.

### BRIEF DESCRIPTION OF THE DRAWINGS

A full understanding of the disclosed concept can be gained from the following description of the preferred embodiments when read in conjunction with the accompanying drawings in which:

FIG. 1 is an isometric view of portions of a Rogowski coil in accordance with embodiments of the disclosed concept.

FIG. 2 is an isometric view of the Rogowski coil of FIG. 1.

FIG. 3 is an isometric view of the core of FIG. 1.

FIG. 4 is a block diagram of a medium voltage electrical apparatus in accordance with another embodiment of the disclosed concept.

### DESCRIPTION OF THE PREFERRED EMBODIMENTS

As employed herein, the term “number” shall mean one or an integer greater than one (i.e., a plurality).

As employed herein, the term “processor” means a programmable analog and/or digital device that can store, retrieve, and process data; a computer; a workstation; a personal computer; a microprocessor; a microcontroller; a microcomputer; a central processing unit; a mainframe computer; a mini-computer; a server; a networked processor; or any suitable processing device or apparatus.

As employed herein, the term “winding” means an elongated conductor wound or coiled about a core such that the winding includes a plurality of turns of the elongated conductor.

As employed herein, the term “shoulder-to-shoulder” refers to a winding where each winding turn of a conductor (e.g., wire) on the outside of a Rogowski coil core, on a Rogowski coil winding or on the insulator for the Rogowski coil winding, is against at least another such winding turn with no or relatively very little gap (e.g., less than or equal to about one-half of the wire diameter) therebetween.

As employed herein, the term “low voltage” shall mean any voltage that is less than about 600 V_{RMS}.

As employed herein, the term “medium voltage” shall mean any voltage greater than a low voltage and in the range from about 600 V_{RMS} to about 52 kV_{RMS}.

As employed herein, the term “medium voltage electrical apparatus” refers to medium voltage electrical switching apparatus and/or medium voltage electrical equipment protection apparatus.

The disclosed concept is described in association with a three-pole medium voltage electrical switching apparatus (e.g., without limitation, medium voltage circuit interrupters; medium voltage circuit breakers; medium voltage contactors), although the disclosed concept is applicable to a wide range of medium voltage electrical switching apparatus and medium voltage electrical equipment protection apparatus (e.g., without limitation, medium voltage motor starters) having any number of poles that sense a number of currents.

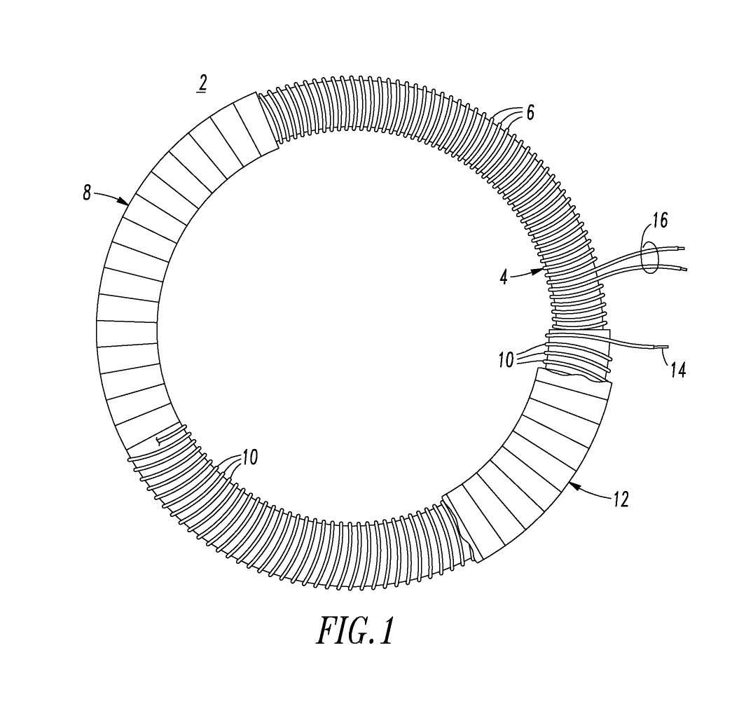

Referring to FIG. 1, portions of a Rogowski coil 2 are shown. The Rogowski coil 2 includes a core 4 (best shown in FIG. 3), a Rogowski coil winding 6 (e.g., an insulated conductor) disposed on the core 4, an insulator 8 (e.g., without limitation, layer insulation, such as Kapton® tape; any suitable flexible insulating tape that conforms to the curve of the core 4; an insulator structured to provide mechanical protection for the winding 6 during subsequent assembly operations) disposed on the Rogowski coil winding 6 disposed on the core 4, and an outer conductive winding 10 disposed on the insulator 8 disposed on the Rogowski coil winding 6 disposed on the core 4.

Layer insulation (as shown by the example insulator 8) is not required, but by having it, the other conductive winding 10 will lay down smoother thereby reducing the number and size of gaps in the outer conductive layer. Alternatively, or in addition, the Rogowski coil winding 6 is an insulated conductor.

For simplicity of illustration, only portions of the Rogowski coil winding 6, the insulator 8 and the conductive winding 10 are shown, such that other components are visible. It will be appreciated that the Rogowski coil winding 6, the insulator 8 and the conductive winding 10 are preferably disposed over and around the core 4. Preferably, a suitable outer protective insulation layer 12 (e.g., without limitation, Kapton® tape) is disposed on the conductive winding 10 over and around the core 4.

The conductive winding 10 includes an electrical connection 14 (e.g., without limitation, one end of the conductive winding 10) structured to be grounded. The Rogowski coil winding 6 also includes an output 16 (e.g., without limitation, opposite ends or leads of the Rogowski coil winding 6). When the conductive winding 10 is grounded, the grounded conductive winding provides electrostatic shielding for the Rogowski coil winding 6 of the Rogowski coil 2. Hence, the outer grounded conductive winding provides an electrostatic shield for the Rogowski coil winding 6.

### Example 1

The conductive winding 10 can be a winding of a suitably fine insulated conductor (e.g., without limitation, an insulated copper wire; a relatively tightly wound magnet wire) wound on top of the Rogowski coil winding 6 to isolate the Rogowski coil winding 6 from electrostatic interference. The conductive winding 10, thus, provides an isolation coil. Preferably, the conductive winding 10 is wound “shoulder-to-shoulder” on the Rogowski coil winding 6 and is grounded at one end or lead 14 of the conductive winding 10 to provide isolation. The conductive winding 10 is electrically insulated from the Rogowski coil winding 6 by the insulator 8 (or, for example and without limitation, by another suitable insulator; by insulation of an insulated conductive winding; by insulation of the Rogowski coil winding). This provides a simple, yet very effective, solution to the problem of effectively and efficiently providing isolation for the Rogowski coil winding 6 to eliminate electrostatic interference.

### Example 2

The example conductive winding 10 can be a helical coil of a conductor.

### Example 3

When grounded, the conductive winding 10 is structured to provide isolation to eliminate medium voltage electrostatic interference for the Rogowski coil winding 6 of the Rogowski coil 2.

### Example 4

The example conductive winding 10 and/or the example Rogowski coil winding 6 can be an insulated conductive winding.

### Example 5

The example conductive winding 10 and the insulator 8 can alternatively be formed by a shoulder-to-shoulder winding of an insulated conductor wound on the Rogowski coil winding 6 to isolate such Rogowski coil winding from medium voltage electrostatic interference. The Rogowski coil winding 6 need not be wound shoulder-to-shoulder.

### Example 6

The example conductive winding 10 can be an isolation coil wound shoulder-to-shoulder on the insulator 8. When such isolation coil is grounded at the end or lead 14 thereof, this isolates the Rogowski coil winding 6 from medium voltage electrostatic interference. The other end of the isolation coil can be left open and be insulated, for example and without limitation, with a small fold of tape. This prevents the sharp end from accidently penetrating the insulation of the adjacent turn. Alternatively, if both ends of the isolation coil are brought out of the Rogowski coil 2, then one end is grounded and the other end is left open and is suitably insulated.

### Example 7

The example conductive winding 10 includes the end or lead 14 thereof that can form a ground terminal, which is structured to be grounded.

### Example 8

The example Rogowski coil winding 6 can be a helical coil of a conductor.

### Example 9

The example insulator 8 can be a layer of insulation or any suitable insulator.

### Example 10

The example conductive winding 10, when grounded, can be structured to provide electrostatic shielding from medium voltage electrostatic interference for the Rogowski coil winding 6 of the Rogowski coil 2.

### Example 11

The example Rogowski coil winding 6 and the example conductive winding 10 can preferably be two evenly distributed layers. The Rogowski coil winding 6 can be formed as a first layer, the conductive winding 10 can be formed as a second layer on the first layer, and the first and second layers can be evenly distributed layers on the core 4. The first layer is the Rogowski coil winding 6 wound, for example, clockwise, and the second layer is the conductive winding 10 wound, for example, counterclockwise. However, the direction of the conductive winding 10 can be reversed. The direction of the Rogowski coil winding 6 determines the polarity of the Rogowski coil 2. The windings 6 and 10 can be formed from, for example and without limitation, 1800 total turns for each of the windings 6,10 of #37 AWG copper wire.

This provides, for example, an electrostatic shield that is not subject to be wrinkled or otherwise altered or damaged.

Furthermore, this provides a simple, yet effective, electrostatic shield that can readily be manufactured using essentially the same winding procedure as that of the Rogowski coil winding 6 regardless of the direction of the conductive winding 10 (e.g., counterclockwise vs. clockwise; clockwise vs. counterclockwise; left-hand vs. right-hand winding polarity; right-hand vs. left-hand winding polarity).

### Example 12

The output 16 and the end or lead 14 can each be formed of an example #26 AWG insulated wire made of twelve strands of #36 AWG copper wire.

### Example 13

The example Rogowski coil 2 can have a DC resistance of about 105 ohms, and an inductance at 1 kHz/1 VAC of about 1.7 mH.

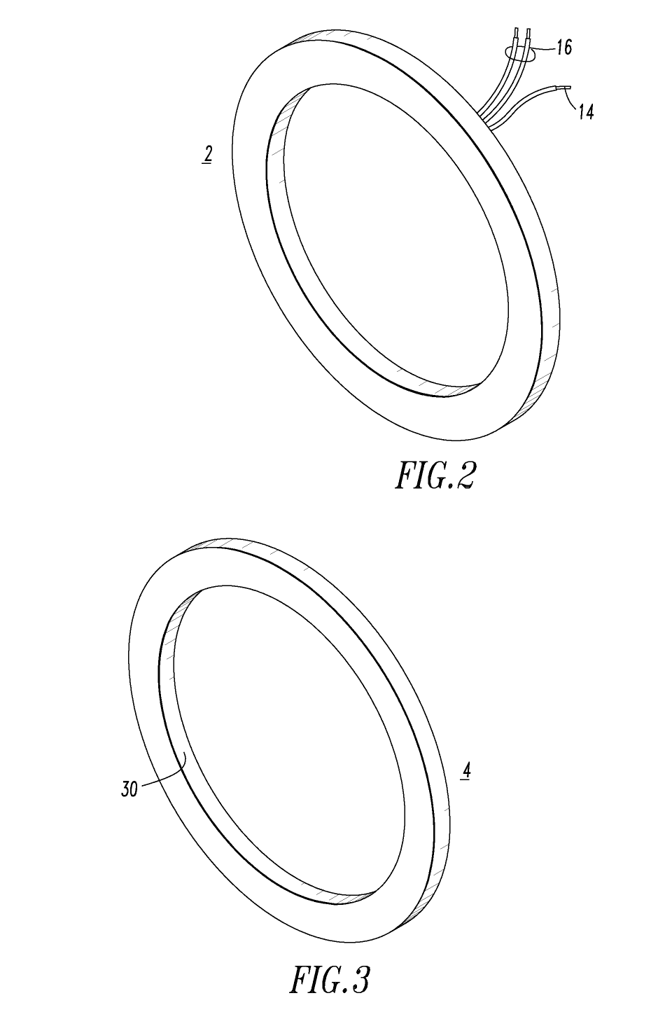

FIG. 2 shows the Rogowski coil 2 of FIG. 1. When the end or lead 14 of the conductive winding 10 (FIG. 1) is suitably grounded, the grounded conductive winding provides electrostatic shielding from medium voltage electrostatic interference for the Rogowski coil winding 6 of the Rogowski coil 2.

### Example 14

FIG. 3 shows the core 4 of FIG. 1. The example core 4 can be an air core made of a suitable plastic (e.g., without limitation, Rynite® FR530 black). As a non-limiting example, the example core 4 has an inside diameter of about 2.56 inches, an outside diameter of about 3.175 inches and a width of about 0.32 inches.

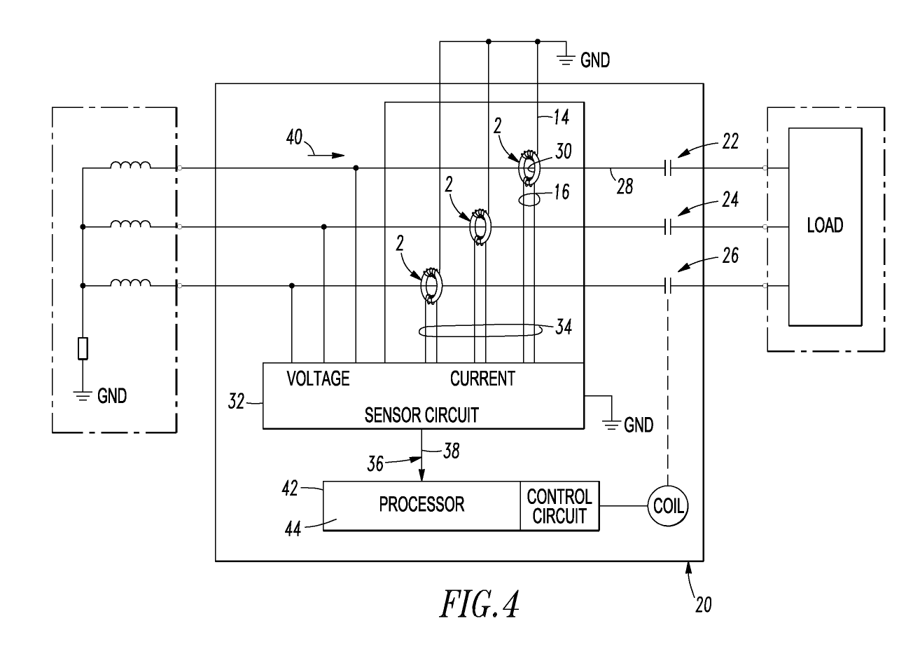

FIG. 4 shows a medium voltage electrical apparatus, such as the example medium voltage electrical switching apparatus 20 (e.g., without limitation, a medium voltage circuit interrupter; a medium voltage contactor) including at least one Rogowski coil 2, as shown in FIGS. 1 and 2. The example medium voltage electrical switching apparatus 20 includes at least one pole (e.g., phase) 22,24,26 (e.g., without limitation, three example poles 22,24,26 are shown) including a medium voltage conductor 28, and the Rogowski coil 2 including an opening 30. A sensor circuit 32 includes an input 34 electrically interconnected with the output 16 of the Rogowski coil 2 and an output 36 having a value 38 corresponding to current 40 flowing through the medium voltage conductor 28. A processor 42 cooperates with the sensor circuit 32 to provide a value 44 of the current 40 flowing through the medium voltage conductor 28. The medium voltage conductor 28 passes through the opening 30 of the core 4 (FIG. 3) of the Rogowski coil 2. When the conductive winding 10 (FIG. 1) is grounded (GND), the grounded conductive winding provides electrostatic shielding for the Rogowski coil winding 6 (FIG. 1) of the Rogowski coil 2.

### Example 15

The example medium voltage electrical switching apparatus 20 can be a three-pole medium voltage electrical switching apparatus.

### Example 16

The example medium voltage electrical apparatus can be a three-pole medium voltage electrical equipment protection apparatus.

### Example 17

A voltage is induced in the Rogowski coil winding 6 proportional to the rate of change of the current 40 flowing through the medium voltage conductor 28.

The Rogowski coil winding 6 is employed for current sensing and the grounded conductive winding 10 is employed for electrostatic shielding. The analog output of the Rogowski coil 2 is input into an analog-to-digital converter (ADC) (not shown), the output of which is suitably conditioned and scaled. The output digitized values are used by an integrator (not shown) of, for example and without limitation, a motor protection algorithm (not shown), and the same output digitized values are used in a ground fault algorithm (not shown) by summing, for example, three-phase current values. The sum is the derivative of ground current. The only difference in the signal into and out of the integrator is a 90 degree phase shift.

### Example 18

As shown in FIG. 4, the end or lead 14 of the isolation coil is suitably grounded (GND). For example and without limitation, a relatively large conductor (e.g., without limitation 14 AWG) is electrically connected to a contactor or starter ground bus GND. The ground for the sensor circuit 32 (e.g., without limitation, including an analog to digital converter (e.g., without limitation, an ADC; a number of ADC channels)) is directly electrically connected to the same contactor or starter ground bus GND.

The disclosed concept provides what is believed to be the simplest, the easiest to implement (e.g., the core 4 is already on the winding machine (not shown) for the Rogowski coil winding 6 and such machine can be employed to wind the conductive winding 10 in the same or different winding direction), and the least expensive as compared to known electrostatic shielding techniques.

While many Rogowski coil applications ignore electrostatic offsets, the disclosed concept enables electrostatic offset of the example Rogowski coil 2 to be effectively reduced or eliminated to enable sensing of plural phase, relatively low level ground fault currents.

The disclosed Rogowski coil 2 provides a linear output over a wide range of currents. In conventional current transformers, different styles (e.g., without limitation, 12) with different current ranges of such current transformers are employed to provide a suitable low end accuracy and a suitable high end linearity. A reduction in the number of styles requires increasing the cross section of the iron core of the current transformer to decrease the flux density during short circuit events. By using the disclosed Rogowski coil 2, the number of styles can be reduced to one.

While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the full breadth of the claims appended and any and all equivalents thereof.

What is claimed is:

1. A Rogowski coil comprising:
a core;
a Rogowski coil winding disposed on said core;
an insulator disposed on said Rogowski coil winding disposed on said core; and
a conductive winding disposed on said insulator disposed on said Rogowski coil winding disposed on said core, said conductive winding including an electrical connection structured to be grounded,
wherein when said conductive winding is grounded, said grounded conductive winding provides electrostatic shielding for said Rogowski coil winding of said Rogowski coil.

2. The Rogowski coil of claim 1 wherein said grounded conductive winding is structured to provide electrostatic shielding from medium voltage electrostatic interference for said Rogowski coil winding of said Rogowski coil.

3. The Rogowski coil of claim 1 wherein said conductive winding is a helical coil of a conductor.

4. The Rogowski coil of claim 1 wherein said grounded conductive winding is structured to provide isolation to eliminate medium voltage electrostatic interference for said Rogowski coil winding of said Rogowski coil.

5. The Rogowski coil of claim 1 wherein said core is an air core.

6. The Rogowski coil of claim 1 wherein said conductive winding is an insulated conductive winding.

7. The Rogowski coil of claim 1 wherein said conductive winding and said insulator are formed by a shoulder-to-shoulder winding of an insulated conductor wound on said Rogowski coil winding to isolate said Rogowski coil winding from medium voltage electrostatic interference.

8. The Rogowski coil of claim 1 wherein said conductive winding is an isolation coil wound shoulder-to-shoulder on said insulator; and wherein said isolation coil is grounded at one end thereof to isolate said Rogowski coil winding.

9. The Rogowski coil of claim 1 wherein said conductive winding comprises an end including a ground terminal; and wherein said ground terminal is structured to be grounded.

10. The Rogowski coil of claim 1 wherein said Rogowski coil winding is a helical coil of a conductor.

11. The Rogowski coil of claim 1 wherein said Rogowski coil winding is formed as a first layer; wherein said conductive winding is formed as a second layer on said first layer; and wherein said first and second layers are evenly distributed layers on said core.

12. The Rogowski coil of claim 11 wherein said Rogowski coil winding is wound in a first winding direction; and wherein said conductive winding is wound in an opposite second winding direction.

13. A medium voltage electrical apparatus comprising:
at least one pole comprising:
a medium voltage conductor, and
a Rogowski coil comprising:
a core including an opening,
a Rogowski coil winding disposed on said core, said Rogowski coil winding defining an output,
an insulator disposed on said Rogowski coil winding disposed on said core, and
a conductive winding disposed on said insulator disposed on said Rogowski coil winding disposed on said core, said conductive winding including an electrical connection structured to be grounded;
a sensor circuit including an input electrically interconnected with the output of the Rogowski coil and an output having a value corresponding to current flowing through the medium voltage conductor; and
a processor cooperating with said sensor circuit to provide a value of the current flowing through said medium voltage conductor,
wherein said medium voltage conductor passes through the opening of said core, and
wherein when said conductive winding is grounded, said grounded conductive winding provides electrostatic shielding for said Rogowski coil winding of said Rogowski coil.

14. The medium voltage electrical apparatus of claim 13 wherein said medium voltage electrical apparatus is a three-pole medium voltage electrical switching apparatus.

15. The medium voltage electrical apparatus of claim 13 wherein said medium voltage electrical apparatus is a three-pole medium voltage electrical equipment protection apparatus.

16. The medium voltage electrical apparatus of claim 13 wherein a voltage is induced in said Rogowski coil winding proportional to the rate of change of said current flowing through said medium voltage conductor.

17. The medium voltage electrical apparatus of claim 13 wherein said insulator is a layer of insulation.

18. The medium voltage electrical apparatus of claim 13 wherein said grounded conductive winding is structured to provide electrostatic shielding from medium voltage electrostatic interference for said Rogowski coil winding of said Rogowski coil.

19. The medium voltage electrical apparatus of claim 13 wherein said conductive winding and said insulator are formed by a shoulder-to-shoulder winding of an insulated conductor wound on said Rogowski coil winding to isolate said Rogowski coil winding from medium voltage electrostatic interference.

20. The medium voltage electrical apparatus of claim 13 wherein said conductive winding is an isolation coil wound shoulder-to-shoulder on said insulator; and wherein said isolation coil is grounded at one end thereof to isolate said Rogowski coil winding.

21. A method of providing electrostatic shielding for a Rogowski coil, said method comprising:
disposing a Rogowski coil winding on a core;
disposing an insulator on said Rogowski coil winding disposed on said core;
disposing a conductive winding on said insulator disposed on said Rogowski coil winding disposed on said core;
grounding said conductive winding; and
providing electrostatic shielding for said Rogowski coil winding of said Rogowski coil with said grounded conductive winding.

22. The method of claim 21 further comprising:
forming said conductive winding and said insulator by a shoulder-to-shoulder winding of an insulated conductor wound on said Rogowski coil winding to isolate said Rogowski coil winding from medium voltage electrostatic interference.

23. The method of claim 21 further comprising:
forming said conductive winding from an isolation coil wound shoulder-to-shoulder on said insulator; and
grounding said isolation coil at one end thereof to isolate said Rogowski coil winding.
